(19) United States
(12) Patent Application Publication
(10) Pub. No.: US 2025/0331370 A1
(43) Pub. Date: Oct. 23, 2025

(54) DISPLAY PANEL, METHOD OF MANUFACTURING DISPLAY PANEL AND ELECTRONIC DEVICE

(71) Applicants: Hefei Visionox Technology Co., Ltd., Hefei (CN); VISIONOX TECHNOLOGY INC., Kunshan (CN)

(72) Inventors: Liusong NI, Hefei (CN); Chung-Chun LEE, Hefei (CN); Yi-Yu LAI, Hefei (CN); Jen-Yu LEE, Hefei (CN); Bowen YANG, Hefei (CN)

(73) Assignees: Hefei Visionox Technology Co., Ltd., Hefei (CN); VISIONOX TECHNOLOGY INC., Kunshan (CN)

(21) Appl. No.: 19/180,394

(22) Filed: Apr. 16, 2025

(30) Foreign Application Priority Data
Apr. 19, 2024 (CN) 202410477141.6
Aug. 30, 2024 (CN) 202411211668.0

(51) Int. Cl. H10K 59/122; H10K 59/12; H10K 59/80

(52) U.S. Cl. CPC H10K 59/122; H10K 59/1201; H10K 59/80515; H10K 59/80517

(57) ABSTRACT

A display panel, a method of manufacturing a display panel, and an electronic device. The display panel includes an array substrate; first electrodes located on a side of the array substrate; an insulating layer located on a side of the first electrode away from the array substrate. The insulating layer includes first openings, the first opening exposes a central area of the first electrode, and edge areas of the first electrode are covered by the insulating layer; and the thickness of the insulating layer is greater than or equal to the thickness of the first electrode.

### CROSS-REFERENCE TO RELATED APPLICATIONS

This application claims priorities to Chinese Patent Application Nos. 202410477141.6, filed on Apr. 19, 2024, and No. 202411211668.0, filed on Aug. 30, 2024, the disclosures of which are incorporated herein by reference in their entireties.

### TECHNICAL FIELD

The present application relates to the field of display technology, and more specifically, to a display panel, a method of manufacturing a display panel and an electronic device.

### BACKGROUND

Organic light-emitting diodes (OLED) and flat panel display devices based on technologies such as light-emitting diodes (LED) are widely used in various consumer electronics such as mobile phones, televisions, laptops, desktop computers, etc. due to their advantages of high image quality, low power consumption, thin body and wide application range, and have become the mainstream in display devices.

However, the process performance of current OLED display products needs to be improved.

### SUMMARY

In order to overcome the above-mentioned deficiency in the prior art, an aspect of the present application is to provide a display panel, the display panel includes: an array substrate, an insulating layer, multiple first electrodes and a light-emitting unit.

The insulating layer is located on a side of the array substrate and includes multiple first openings.

The multiple first electrodes are located on a side of the array substrate and arranged at intervals. Specifically, the first electrode includes a portion exposed from the first opening, side surface of the first electrode is covered by the insulating layer, and the thickness of the insulating layer is greater than or equal to the thickness of the first electrode.

The light-emitting unit is located on a side of the first electrode away from the array substrate.

In some possible implementations, the insulating layer includes a first insulating portion covering the first electrode and a second insulating portion not covering the first electrode, and the ratio of the thickness of the first insulating portion to the thickness of the first electrode is greater than or equal to 1.

A display panel according to some embodiments of the present application includes: an array substrate, an insulating layer, multiple first electrodes, a light-emitting unit and a second electrode.

The insulating layer is located on a side of the array substrate, and includes first openings.

The multiple first electrodes are located on a side of the array substrate and arranged at intervals. Specifically, a first electrode of the multiple first electrodes includes a portion exposed from a first opening of the first openings, the insulating layer includes a first insulating portion covering the first electrode and a second insulating portion staggered with the first electrode, and the thickness of the insulating layer at the junction of the first insulating portion and the second insulating portion is greater than the thickness of the first electrode corresponding to the first insulating portion.

The light-emitting unit is located on a side of the first electrode away from the array substrate.

The second electrode is located on a side of the light-emitting unit away from the array substrate.

A method of manufacturing a display panel according to the present application includes:
providing an array substrate;
arranging first electrodes on a side of the array substrate;
providing an insulating layer on a side of the first electrodes away from the array substrate, specifically, the insulating layer includes first openings, a first electrode of the first electrodes includes a portion exposed from a first opening of the first openings, and a side surface of the first electrode is covered by the insulating layer; and the thickness of the insulating layer is greater than or equal to the thickness of the first electrode; and
forming a light-emitting unit located on the side of the first electrode away from the array substrate.

In some possible implementations, the step of providing an insulating layer on a side of the first electrode away from the array substrate includes:
providing an insulating layer with a thickness greater than or equal to 1000 angstroms on the side of the first electrode away from the array substrate.

### BRIEF DESCRIPTION OF DRAWINGS

FIG. 1 is a first schematic structural diagram of a display panel according to this embodiment;

FIG. 2 is a second schematic structural diagram of a display panel according to this embodiment;

FIG. 3 is a third schematic structural diagram of a display panel according to this embodiment;

FIG. 4 is a fourth schematic structural diagram of a display panel according to this embodiment;

FIG. 5 is a fifth schematic structural diagram of a display panel according to this embodiment;

FIG. 6 is a sixth schematic structural diagram of a display panel according to this embodiment;

FIG. 7 is a seventh schematic structural diagram of a display panel according to this embodiment;

FIG. 8 is a schematic diagram of an isolation structure according to this embodiment;

FIG. 9 is an eighth schematic structural diagram of a display panel according to this embodiment;

FIG. 10 is a ninth schematic structural diagram of a display panel according to this embodiment;

FIG. 11 is a schematic diagram of a method of manufacturing a display panel according to this embodiment;

FIG. 12 is a first schematic diagram of a process of manufacturing a display panel according to this embodiment; and

FIG. 13 is a second schematic diagram of a process of manufacturing a display panel according to this embodiment.

### DETAILED DESCRIPTION

The following detailed description of the embodiments of the present application provided in the accompanying drawings is not intended to limit the scope of the application claimed, but merely represents selected embodiments of the present application.

The inventor has found through study that in the conventional OLED display panel, the display panel generally includes an array substrate, a first electrode (such as an anode) located on a side of the array substrate, and an insulating layer (such as a pixel defining layer) located on a side of the first electrode away from the array substrate. Specifically, the insulating layer is generally required to cover at least part of the first electrode (such as the edge of the first electrode). In this case, if the thicknesses of the first electrode and the insulating layer are not set properly, the first electrode may be damaged in the subsequent etching operation of other film layers, adversely affecting the yield of the display panel.

In view of this, a solution that can reduce the risk of damage to the first electrode is provided according to this embodiment, and the solution according to this embodiment is described in detail below.

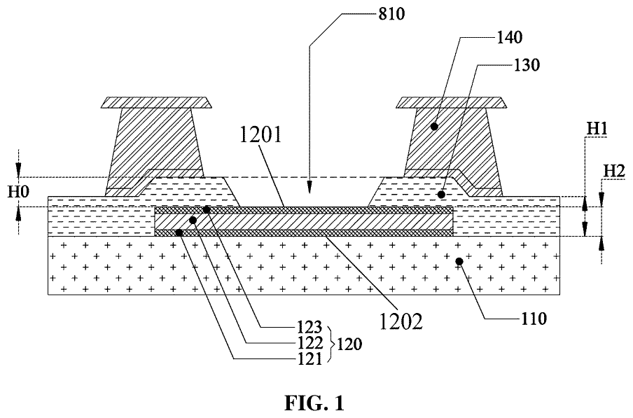

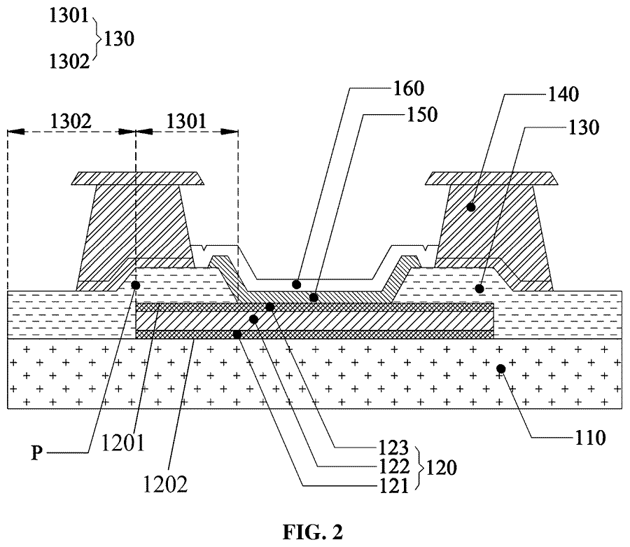

Reference is made to FIG. 1 and FIG. 2, which show a display panel according to this embodiment, and the display panel may include an array substrate 110, a first electrode 120, an insulating layer 130 and a light-emitting unit 150.

In this embodiment, the array substrate 110 may include multiple film layer structures, such as a substrate, a buffer layer, an active layer, multiple metal layers, multiple insulating layers and a planarization layer. The multiple film layer structures of the array substrate 110 can form multiple thin film transistors (TFTs) at different positions of the array substrate 110, and the thin film transistors can cooperate with each other to form multiple pixel driving units or pixel driving circuits.

The insulating layer 130 is located on a side of the first electrode 120 away from the array substrate 110, and the insulating layer 130 includes first openings 810.

Multiple first electrodes 120 are located on a side of the array substrate 110, and the multiple first electrodes 120 are arranged at intervals. The first electrode 120 includes a portion exposed from a first opening 810, and a side surface of the first electrode 120 is covered by the insulating layer 130. For example, the first opening 810 exposes the central area of the first electrode 120, and the edge areas of the first electrode 120 are covered by the insulating layer 130. That is, the insulating layer 130 extends along the side surface of the first electrode 120 to the side of the first electrode 120 away from the array substrate 110, and covers at least part of the side of the first electrode 120 away from the array substrate 110.

In this embodiment, a thickness H1 of the insulating layer 130 is greater than or equal to a thickness H2 of the first electrode 120. The thickness of the insulating layer 130 is the minimum distance from a side of the insulating layer 130 away from the array substrate 110 to a side of the insulating layer 130 close to the array substrate 110 in the direction perpendicular to the array substrate 110. Due to process errors, process design, subsequent process influences, etc., the thickness of the insulating layer at the edge positions may be thinned and uneven. Therefore, the thickness of the insulating layer in this application refers to the thickness of a uniform part of the insulating layer.

The light-emitting unit 150 is at least partially located in the first opening 810 and on the side of the first electrode 120 away from the array substrate 110. The light-emitting unit 150 may include a hole injection layer, a hole transport layer, an electron blocking layer, etc.

Optionally, the display panel according to this embodiment may further include a second electrode 160 located on a side of the light-emitting unit 150 away from the array substrate 110.

Based on the above design, in this embodiment, by setting the thickness of the insulating layer 130 to be greater than the thickness of the first electrode 120, the risk of forming fractures of the insulating layer 130 covering the edges of the first electrode 120 can be reduced, and the etching liquid is prevented from invading the first electrode 120 through the fracture of the insulating layer 130 in the subsequent patterning etching of other film layers, thereby protecting the first electrode 120 and ensuring the yield of the display panel.

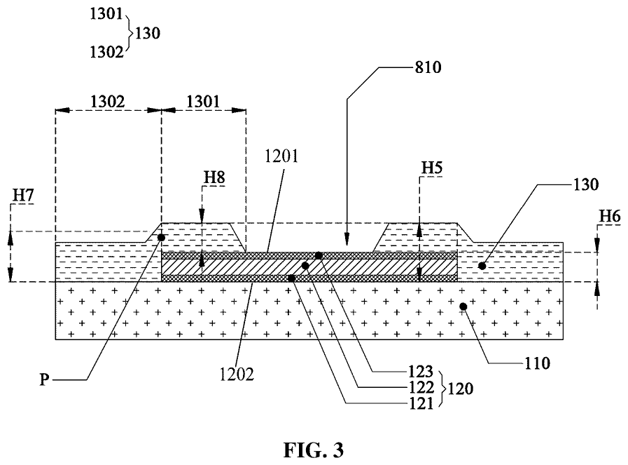

In some possible implementations, referring to FIG. 3, the insulating layer 130 includes a first insulating portion 1301 covering the first electrode 120 and a second insulating portion 1302 not covering the first electrode 120. That is, the orthographic projection of the first insulating portion 1301 on the array substrate 110 overlaps the orthographic projection of the first electrode 120 on the array substrate, and the orthographic projection of the second insulating portion on the array substrate has no overlap with the orthographic projection of the first electrode 120 on the array substrate. The ratio of the thickness of the first insulating portion 1301 to the thickness of the first electrode 120 is greater than or equal to 1.

In some possible implementations, the thickness of the first electrode 120 is about 1000 angstroms, and therefore, the thickness of the insulating layer 130 is greater than or equal to 1000 angstroms.

Optionally, the thickness of the insulating layer 130 ranges from 2000 angstroms to 4000 angstroms. In this way, it can be ensured that the insulating layer 130 can better cover the edges of the first electrode 120, reducing the risk of the insulating layer 130 having fractures.

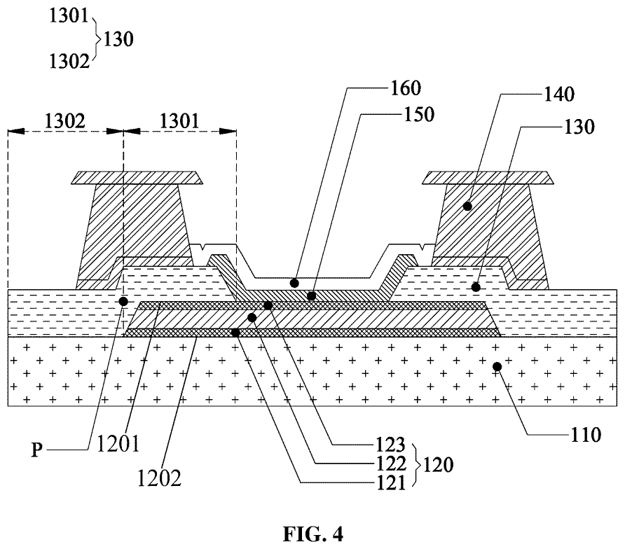

In some possible implementations, referring to FIG. 4, the first electrode 120 includes a first surface 1201 on the side away from the array substrate 110 and a second surface 1202 on a side close to the array substrate 110.

Optionally, the orthographic projection of the first surface 1201 on the array substrate 110 is located within the orthographic projection of the second surface 1202 on the array substrate 110.

For example, in this embodiment, on a cross section perpendicular to the array substrate 110, the cross-sectional shape of the first electrode 120 may be a rectangle. In this case, the first insulating portion 1301 is a portion of the insulating layer 130 that covers the side of the first electrode 120 away from the array substrate 110.

For another example, in this embodiment, on a cross section perpendicular to the array substrate 110, the cross-sectional shape of the first electrode 120 may be a trapezoid, and a longer bottom side of the trapezoid is located on the side close to the array substrate 110. In this case, the first insulating portion 1301 is a portion of the insulating layer 130 that covers the side of the first electrode 120 away from the array substrate 110 and the side surface of the first electrode 120.

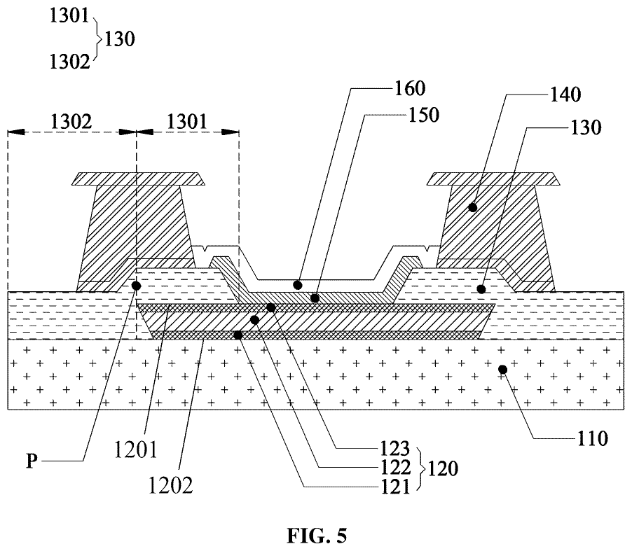

Alternatively, referring to FIG. 5, optionally, the orthographic projection of the second surface 1202 on the array substrate 110 is located within the orthographic projection of the first surface 1201 on the array substrate 110.

For example, in this embodiment, on a cross section perpendicular to the array substrate 110, the cross-sectional shape of the first electrode 120 may be a trapezoid, and a longer bottom side of the trapezoid is located on the side away from the array substrate 110. In this case, the first insulating portion 1301 is a portion of the insulating layer 130 that covers the side of the first electrode 120 away from the array substrate 110.

It should be noted that, in the case where the first electrode 120 has multiple film layers, the cross-sectional shape of the first electrode 120 may be a trapezoid as a whole, but the side surface of the first electrode 120 may form a stepped or serrated structure due to the etching process or the different etching resistances of different film layers. Due to process errors, process design, subsequent process influences, etc., the thickness of the first electrode 120 at the edge positions may be thinned, uneven, etc. Therefore, the thickness of the first electrode 120 in this application refers to the thickness of a uniform part of the electrode layer.

In some possible implementations, the insulating layer 130 may be a pixel defining layer, the first opening 810 may be a pixel opening, and the material of the insulating layer 130 is an inorganic material.

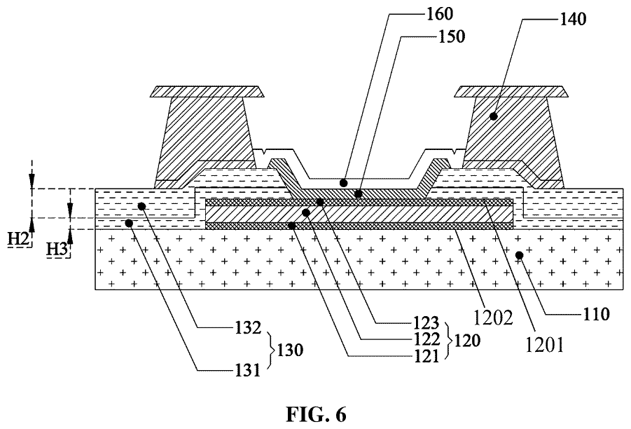

In some possible implementations, referring to FIG. 6, the insulating layer 130 includes a first sublayer 131 and a second sublayer 132 stacked in a direction away from the array substrate 110, and silicon contents in the first sublayer 131 and the second sublayer 132 are different.

Optionally, the ratio of nitrogen content to silicon content in the first sublayer 131 is a first ratio, the ratio of nitrogen content to silicon content in the second sublayer 132 is a second ratio, and the first ratio is different from the second ratio.

In some possible implementations, the materials of the first sublayer 131 and the second sublayer 132 can both be silicon nitride, but the first ratio is different from the second ratio.

For example, in the formation processes of the first sublayer 131 and the second sublayer 132, different powers can be used to bombard the silicon target in an environment containing nitrogen to form the first sublayer 131 and the second sublayer 132.

In other possible implementations, the material of the first sublayer 131 can be silicon nitride, and the material of the second sublayer 132 can be silicon oxide.

In some possible implementations, the first ratio is X, and the second ratio is Y, specifically, 0<X<¾, and 0≤Y<¾, and X>Y.

On this basis, optionally, when Y=0, a thickness H2 of the second sublayer 132 is less than a thickness H3 of the first sublayer 131; and when Y≠0, the thickness H2 of the second sublayer 132 is greater than the thickness H3 of the first sublayer 131.

Optionally, the thickness H3 of the first sublayer 131 ranges from 0 angstroms to 3000 angstroms, and the thickness H2 of the second sublayer 132 ranges from 0 A to 4000 A.

In some possible implementations, referring to FIG. 1 and FIG. 2, the first electrode 120 includes a first conductive layer 121, a second conductive layer 122, and a third conductive layer 123 stacked in a direction away from the array substrate 110, and the etching rate of the second conductive layer 122 is different from the etching rates of the first conductive layer 121 and the third conductive layer 123.

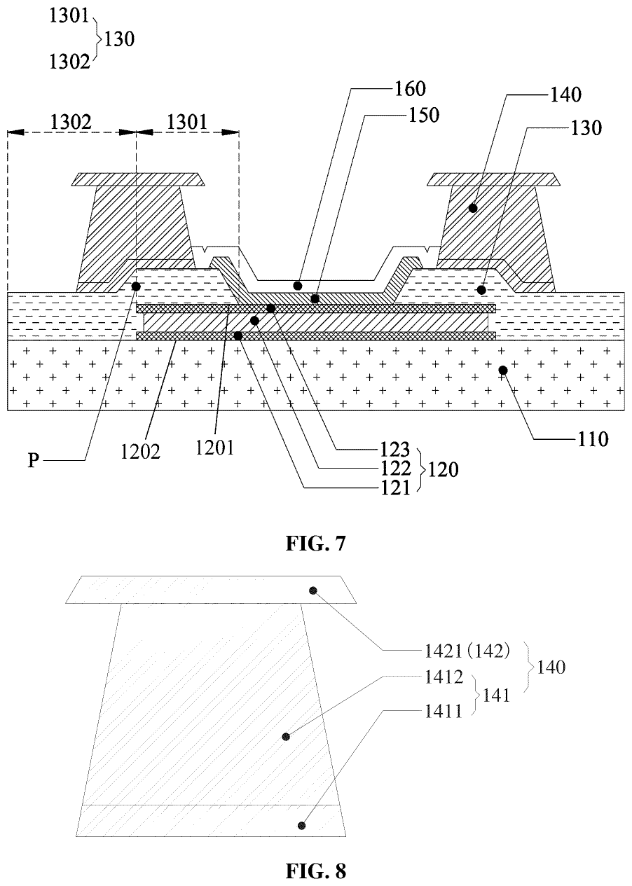

Optionally, referring to FIG. 7, the orthographic projection of the second conductive layer 122 on the array substrate 110 is located within the orthographic projection of the first conductive layer 121 and the third conductive layer 123 on the array substrate 110. That is, viewed from the side surface of the first electrode 120, the second conductive layer 122 is shorter than the first conductive layer 121 and the third conductive layer 123, making the cross-sectional shape of the first electrode 120 as a whole I-shaped. In this case, the first insulating portion 1301 is a portion of the insulating layer 130 that covers the side of the first electrode 120 away from the array substrate 110.

For example, the materials of the first conductive layer 121 and the third conductive layer 123 include at least one of indium tin oxide, indium zinc oxide, and indium gallium oxide, and the material of the second conductive layer 122 includes silver. The material of the second conductive layer 122 is silver, which can ensure that the first electrode 120 has a small resistance and ensure its conductivity. The materials of the first conductive layer 121 and the third conductive layer 123 are at least one of indium tin oxide, indium zinc oxide, and indium gallium oxide, which can protect the second conductive layer 122 located between the first conductive layer 121 and the third conductive layer 123, and reduce the risk of oxidation of the second conductive layer 122.

In some possible implementations, referring to FIG. 1 and FIG. 2 again, the display panel according to this embodiment may further include an isolation structure 140.

The isolation structure 140 is located on the side of the insulating layer 130 away from the array substrate 110. The isolation structure 140 includes an isolation opening, and the orthographic projection of the first opening 810 on the array substrate 110 is located within the orthographic projection of the isolation opening on the array substrate 110. The isolation opening is in communication with the first opening 810, and the isolation opening and the first opening 810 expose together at least part of the first electrode 120.

The isolation structure 140 can be used to disconnect the light-emitting units 150 and disconnect the second electrodes 160 between adjacent pixels while the light-emitting units 150 and the second electrodes 160 are subsequently formed by evaporation, so that light-emitting units 150 of different colors can be set in different first openings 810 by full-layer evaporation plus etching.

Relevant technical solutions of the isolation structure 140 are recorded in Patent applications PCT/CN2023/134518, CN202310759370.2, CN202310740412.8, CN202310707209.0, and CN202311346196.5, and the disclosures of these patent applications are incorporated into this application by reference, for reference.

Further, in some possible implementations, the material of the insulating layer 130 is an inorganic material. In this way, the insulating layer 130 is made of an inorganic material with weak water absorption, which can ensure the stability of the insulating layer 130 in the subsequent wet processing of the light-emitting unit 150 and the second electrode 160.

In some possible implementations, referring to FIG. 8, the isolation structure 140 includes a support portion 141 and a blocking portion 142 stacked toward the side away from the array substrate 110, and the orthographic projection of the support portion 141 on the array substrate 110 is located within the orthographic projection of the blocking portion 142 on the array substrate 110. That is, the side surface of the isolation structure 140 forms an undercut structure. In this way, when other organic material layers are subsequently formed by evaporation, these organic material layers can be broken.

In some possible implementations, the support portion 141 includes a first metal layer 1411 and a second metal layer 1412 stacked toward the side away from the array substrate 110, and the blocking portion 142 includes a third metal layer 1421.

Optionally, the material of the first metal layer 1411 includes molybdenum, the material of the second metal layer 1412 includes aluminum, and the material of the third metal layer 1421 includes titanium.

In some possible implementations, at least part of the isolation structure 140 is conductive. Referring to FIG. 2, at least part of the second electrode 160 is located on the side of the light-emitting unit 150 away from the array substrate 110 and is in electrical contact with the light-emitting unit 150, and at least another part of the second electrode 160 is located on the side of the insulating layer 130 away from the array substrate 110 and is in electrical contact with the isolation structure 140. For example, the second electrode 160 extends from within the first opening 810 to the side of the insulating layer 130 away from the array substrate 110 and is in electrical contact with the isolation structure 140.

The first electrode 120 can be connected to a pixel driving circuit in the array substrate 110, and the second electrode 160 can be connected to a common voltage supply circuit through the isolation structure 140. When there is a potential difference between the first electrode 120 and the second electrode 160, the light-emitting unit 150 located between the first electrode 120 and the second electrode 160 is driven to emit light.

In some possible implementations, referring to FIG. 1 again, the orthographic projection of the first electrode 120 on the array substrate 110 at least partially overlaps the orthographic projection of the isolation structure 140 on the array substrate 110, for example, the orthographic projection of the side surface of the first electrode 120 on the array substrate 110 is located within the orthographic projection of the isolation structure 140 on the array substrate 110.

That is, at least part of the first electrode 120 extends below the isolation structure 140. Thus, parasitic capacitance may be formed between the conductive first electrode 120 and the conductive isolation structure 140, resulting in parasitic capacitance between the first electrode 120 and the second electrode 160 which is electrically connected to the isolation structure 140, which may adversely affect the reset effectiveness of the light-emitting device during reset.

In this case, in the display panel according to this embodiment, by increasing the thickness of the insulating layer 130, the distance H0 between the isolation structure 140 and the first electrode 120 can be increased, thereby reducing the parasitic capacitance between the first electrode 120 and the second electrode 160, and ensuring the reset effectiveness of the light-emitting device during reset.

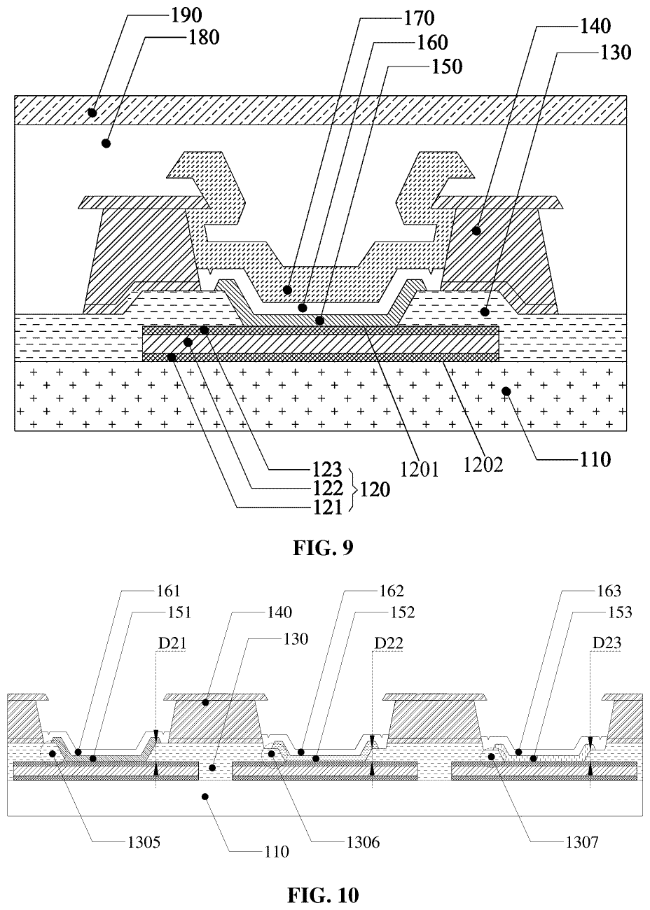

In some possible implementations, referring to FIG. 9, the display panel according to this embodiment may further include a first encapsulation layer 170.

Optionally, the first encapsulation layer 170 may extend from within the first opening 810 to a side of the isolation structure 140 away from the array substrate 110. The first encapsulation layers 170 corresponding to the adjacent first openings 810 may be disconnected on the side of the isolation structure 140 away from the array substrate 110.

Further, in some possible implementations, the display panel according to this embodiment further includes a second encapsulation layer 180 and a third encapsulation layer 190 stacked and arranged on a side of the first encapsulation layer 170 away from the array substrate 110.

Optionally, the materials of the first encapsulation layer 170 and the third encapsulation layer 190 include inorganic materials, and the material of the second encapsulation layer 180 includes an organic material. For example, the first encapsulation layer 170 and the third encapsulation layer 190 may be formed by chemical vapor deposition (CVD), and the second encapsulation layer 180 may be formed by ink-jet printing (IJP).

Optionally, a gap may be formed between the isolation structure 140 and a portion of the first encapsulation layer 170 located at the side of the isolation structure 140 away from the array substrate 110. The second encapsulation layer 180 may fill the gap.

In some possible implementations, referring to FIG. 10, the isolation opening includes a first isolation opening 161 and a second isolation opening 162, the light-emitting unit 150 includes a first light-emitting unit 151 and a second light-emitting unit 152 with different light-emitting colors, at least part of the first light-emitting unit 151 is located in the first isolation opening 161, and at least part of the second light-emitting unit 152 is located in the second isolation opening 162.

The insulating layer 130 includes a first defining portion 1305 extending from the isolation structure 140 corresponding to the first isolation opening 161 and a second defining portion 1306 extending from the isolation structure 140 corresponding to the second isolation opening 162, and the orthographic projection of the first defining portion 1305 on the array substrate 110 is located within the orthographic projection of the first isolation opening 161 on the array substrate 110, that is, the first isolation opening 161 exposes the first defining portion 1305 of the insulating layer 130. The orthographic projection of the second defining portion 1306 on the array substrate 110 is located within the orthographic projection of the second isolation opening 162 on the array substrate 110, that is, the second isolation opening 162 exposes the second defining portion 1306 of the insulating layer 130.

For example, at a position near the first isolation opening 161, the portion of the insulating layer 130 that extends out of the isolation structure 140 relative to the side of the isolation structure 140 closer to the array substrate 110 (that is, not covered by the isolation structure 140) is the first defining portion 1305, and the first defining portion 1305 is exposed from at least part of the first isolation opening 161.

At a position near the second isolation opening 162, the portion of the insulating layer 130 that extends out of the isolation structure 140 relative to the side of the isolation structure 140 closer to the array substrate 110 (that is, not covered by the isolation structure 140) is the second defining portion 1306, and the second defining portion 1306 is exposed from at least part of the second isolation opening 162.

Specifically, a thickness D21 of the first defining portion 1305 and a thickness D22 of the second defining portion 1306 are both greater than the thickness of the first electrode 120.

Optionally, in some possible implementations, the thickness D21 of the first defining portion 1305 is approximately equal to the thickness D22 of the second defining portion 1306.

Optionally, in other possible implementations, the thickness D21 of the first defining portion 1305 is greater than the thickness D22 of the second defining portion 1306.

For example, the first light-emitting unit 151 may be manufactured prior to the manufacturing of the second light-emitting unit 152. During the patterning etching process of the first light-emitting unit 151, the second defining portion 1306 of the insulating layer 130 located in the second isolation opening 162 and not covered by the isolation structure 140 may be etched and thinned accordingly, so that the thickness D21 of the first defining portion 1305 of the insulating layer 130 located in the first isolation opening 161 is greater than the thickness D22 of the second defining portion 1306 located in the second isolation opening 162.

Optionally, the isolation opening further includes a third isolation opening 163, and the light-emitting unit 150 further includes a third light-emitting unit 153 having a light-emitting color different from the light-emitting colors of the first light-emitting unit 151 and the second light-emitting unit 152, and at least part of the third light-emitting unit 153 is located in the third isolation opening 163. For example, the light-emitting colors of the first light-emitting unit 151, the second light-emitting unit 152, and the third light-emitting unit 153 can each be a different one of red, green and blue.

The insulating layer 130 further includes a third defining portion 1307 extending out of the isolation structure 140 corresponding to the third isolation opening 163, and the orthographic projection of the third defining portion 1307 on the array substrate 110 is located within the orthographic projection of the third isolation opening 163 on the array substrate 110, that is, the third isolation opening 163 exposes the third defining portion 1307 of the insulating layer 130.

For example, at a position near the third isolation opening 163, the portion of the insulating layer 130 that extends out of the isolation structure 140 relative to the side of the isolation structure 140 closer to the array substrate 110 (that is, not covered by the isolation structure 140) is the third defining portion 1307, and the third defining portion 1307 is exposed from at least part of the third isolation opening 163.

Specifically, the thickness D21 of the first defining portion 1305, the thickness D22 of the second defining portion 1306, and a thickness D23 of the third defining portion 1307 are all greater than the thickness of the first electrode 120.

Optionally, in some possible implementations, the thickness D22 of the second defining portion 1306 is approximately equal to the thickness D23 of the third defining portion 1307, that is, the thickness D21 of the first defining portion 1305, the thickness D22 of the second defining portion 1306 and the thickness D23 of the third defining portion 1307 are approximately equal.

Optionally, in some other possible implementations, the thickness D22 of the second defining portion 1306 is greater than the thickness D23 of the third defining portion 1307. That is, the thickness D21 of the first defining portion 1305, the thickness D22 of the second defining portion 1306 and the thickness D23 of the third defining portion 1307 decrease in sequence.

For example, the first light-emitting unit 151 may be manufactured prior to the manufacturing of the second light-emitting unit 152, and the second light-emitting unit 152 may be manufactured prior to the manufacturing of the third light-emitting unit 153. During the patterning etching process of the first light-emitting unit 151, the third defining portion 1307 of the insulating layer 130 located in the third isolation opening 163 and not covered by the isolation structure 140 may be etched and thinned accordingly, and the thickness D21 of the first defining portion 1305 of the insulating layer 130 located in the first isolation opening 161 is greater than the thickness D23 of the third defining portion 1307 of the insulating layer 130 located in the third isolation opening 163. Then, during the patterning etching process of the second light-emitting unit 152, the third defining portion 1307 of the insulating layer 130 located in the third isolation opening 163 and not covered by the isolation structure 140 is etched and thinned again, so that the thickness D22 of the second defining portion 1306 of the insulating layer 130 located in the second isolation opening 162 is greater than the thickness D23 of the third defining portion 1307 of the insulating layer 130 located in the third isolation opening 163.

In some possible implementations, in the area where the insulating layer 130 covers the first electrode 120, the ratio of the thickness of the insulating layer 130 to the thickness of the first electrode 120 is greater than or equal to 1. For example, referring to FIG. 2, the insulating layer 130 includes a first insulating portion 1301 and a second insulating portion 1302, the orthographic projection of the first insulating portion 1301 on the array substrate 110 overlaps the orthographic projection of the first electrode 120 on the array substrate 110, and the orthographic projection of the second insulating portion 1302 on the array substrate 110 is staggered with the orthographic projection of the first electrode 120 on the array substrate 110. That is, in the insulating layer 130, the portion covering the first electrode 120 is the first insulating portion 1301, and the portion not covering the first electrode 120 is the second insulating portion 1302.

A distance H5 from a side of the first insulating portion 1301 away from the array substrate 110 to the array substrate 110 is greater than a distance H6 from the side of the first electrode 120 away from the array substrate 110 to the array substrate 110. That is, at least part of the insulating layer 130 covers the side of the first electrode 120 away from the array substrate 110.

In some possible implementations, the display panel according to this embodiment may further include a touch function layer, and the touch function layer may be located on a side of the third encapsulation layer 190 away from the array substrate 110. The touch function layer may include a touch electrode for performing touch detection. Optionally, the touch electrode may be arranged in a self-capacitance detection mode and/or a mutual capacitance detection mode, which is not specifically limited in this embodiment.

In some possible implementations, the display panel according to this embodiment may further include a polarizing layer, and the polarizing layer may be located on the side of the third encapsulation layer 190 away from the array substrate 110. The polarizer can reduce the reflection of the display panel for external light and ensure the display effect of the display panel.

In some possible implementations, the display panel according to this embodiment may further include a cover plate for protecting the display panel, and the cover plate may be located on a side of a film layer farthest from the array substrate 110 away from the array substrate 110.

Referring to FIG. 2 again, the insulating layer 130 is located on the side of the first electrode 120 away from the array substrate 110, and the insulating layer 130 includes first openings 810. The first electrode 120 includes a portion exposed from a first opening 810, for example, the first opening 810 exposes the central area of the first electrode 120, and the edge areas of the first electrode 120 are covered by the insulating layer 130.

The insulating layer 130 includes a first insulating portion 1301 covering the first electrode 120 and a second insulating portion 1302 arranged to be staggered with the first electrode 120. Referring to FIG. 2, FIG. 3, FIG. 4, FIG. 5 or FIG. 7, The junction P between the first insulating portion 1301 and the second insulating portion 1302 of the insulating layer 130 is located at a position close to an end of the first electrode 120. Referring to FIG. 3 again. A thickness H7 of the insulating layer 130 at the junction P of the first insulating portion 1301 and the second insulating portion 1302 is greater than a thickness H8 of the first electrode 120 corresponding to the first insulating portion 1301.

Specifically, the thickness H7 of the insulating layer 130 at the junction P of the first insulating portion 1301 and the second insulating portion 1302 refers to the thickness at this position in the direction perpendicular to the array substrate 110.

The light-emitting unit 150 is at least partially located in the first opening 810 and located on the side of the first electrode 120 away from the array substrate 110. The material of the light-emitting unit 150 includes an electroluminescent material.

In some possible implementations, the side surface of the first electrode 120 is covered by the insulating layer 130. That is, the insulating layer 130 extends along the side surface of the first electrode 120 to the side of the first electrode 120 away from the array substrate 110, and covers at least part of the side of the first electrode 120 away from the array substrate 110. In some possible implementations, the insulating layer 130 may be a pixel defining layer, the first opening 810 may be a pixel opening, and the material of the insulating layer 130 is an inorganic material.

In some possible implementations, referring to FIG. 6, the insulating layer 130 includes a first sublayer 131 and a second sublayer 132 stacked in a direction away from the array substrate 110, and a first ratio of nitrogen content to silicon content in the first sublayer 131 is different from a second ratio of nitrogen content to silicon content in the second sublayer 132.

In some possible implementations, the materials of the first sublayer 131 and the second sublayer 132 may both be silicon nitride, but a first ratio of nitrogen content to silicon content in the first sublayer 131 is different from a second ratio of nitrogen content to silicon content in the second sublayer 132.

In other possible implementations, the material of the first sublayer 131 may be silicon nitride, and the material of the second sublayer 132 may be silicon oxide.

In some possible implementations, the first ratio of nitrogen content to silicon content in the first sublayer 131 is X, and the second ratio of nitrogen content to silicon content in the second sublayer 132 is Y, specifically 0<X<¾, and 0≤Y<¾, and X>Y.

On this basis, optionally, when Y=0, the thickness H2 of the second sublayer 132 is less than the thickness H3 of the first sublayer 131; and when Y≠0, the thickness H2 of the second sublayer 132 is greater than the thickness H3 of the first sublayer 131.

Optionally, the thickness H3 of the first sublayer 131 ranges from 0 angstroms to 3000 angstroms, and the thickness H2 of the second sublayer 132 ranges from 0 A to 4000 A.

In some possible implementations, referring to FIG. 1 again, the orthographic projection of the first electrode 120 on the array substrate 110 at least partially overlaps the orthographic projection of the isolation structure 140 on the array substrate 110, for example, the orthographic projection of the side surface of the first electrode 120 on the array substrate 110 is located within the orthographic projection of the isolation structure 140 on the array substrate 110.

In some possible implementations, referring to FIG. 1 and FIG. 2 again, the display panel according to this embodiment may further include an isolation structure 140.

The isolation structure 140 is located on the side of the insulating layer 130 away from the array substrate 110. The isolation structure 140 includes an isolation opening, and the orthographic projection of the first opening 810 on the array substrate 110 is located within the orthographic projection of the isolation opening on the array substrate 110. The isolation opening is in communication with the first opening 810, and the isolation opening and the first opening 810 expose together at least part of the first electrode 120.

In some possible implementations, referring to FIG. 8, the isolation structure 140 includes a support portion 141 and a blocking portion 142 stacked toward the side away from the array substrate 110, and the orthographic projection of the support portion 141 on the array substrate 110 is located within the orthographic projection of the blocking portion 142 on the array substrate 110. That is, the side surface of the isolation structure 140 forms an undercut structure.

In some possible implementations, the display panel includes a display area and a non-display area (such as a border area) that at least partially surrounds the display area.

The first electrode 120 is located in the display area, and the display panel further includes signal wiring that is arranged in the same layer as the first electrode 120 and is located in the non-display area. The insulating layer 130 continuously covers the side surface of the signal wiring and the side of the signal wiring away from the array substrate 110.

For example, in the display area, the insulating layer 130 covers the edge areas of the first electrode 120 and exposes the central area of the first electrode; and in the non-display area, the insulating layer 130 completely covers the signal wiring that is arranged in the same layer as the first electrode 120.

In this case, the thickness of the insulating layer 130 can be greater than or equal to the thickness of the signal wiring. In this way, it can be ensured that the signal wiring in the non-display area will not be damaged by the etching solution during the patterning etching operation of the isolation structure 140.

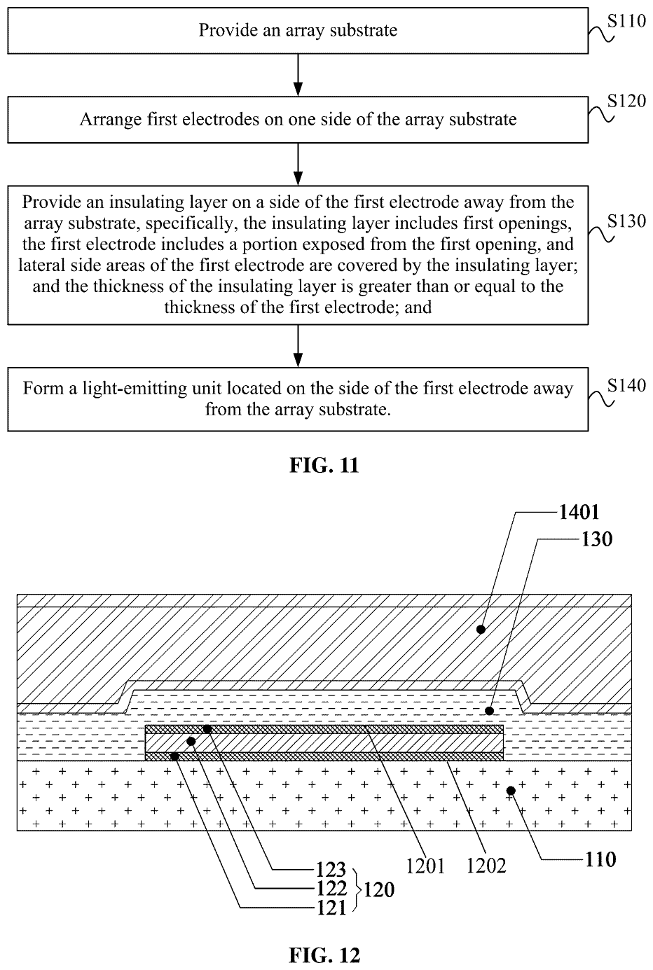

Referring to FIG. 11, a method of manufacturing a display panel is further provided according to this embodiment, and the method may include steps S110 to S140 as follows.

In step S110, an array substrate 110 is provided.

In step S120, first electrodes 120 are arranged on a side of the array substrate 110.

In step S130, an insulating layer 130 is provided on a side of the first electrode 120 away from the array substrate 110, specifically, the insulating layer 130 includes first openings 810, the first electrode 120 includes a portion exposed from the first opening 810, and the side surface of the first electrode 120 is covered by the insulating layer 130. A thickness H1 of the insulating layer 130 is greater than or equal to a thickness H2 of the first electrode 120.

In step S140, a light-emitting unit 150 that is at least partially located in the first opening 810 and located on the side of the first electrode 120 away from the array substrate 110 is formed.

In some possible implementations, in step S130, an insulating layer 130 having a thickness greater than or equal to 1000 angstroms may be provided on the side of the first electrode 120 away from the array substrate 110.

In some possible implementations, after step S130, the method further includes steps S210 to S230 as follows.

In step S210, an isolation layer 1401 is provided on a side of the insulating layer 130 away from the array substrate 110.

For example, referring to FIG. 12, in this embodiment, a fully covering isolation layer 1401 may be formed first.

In step S220, the isolation layer 1401 is etched to form isolation structures 140 having isolation openings.

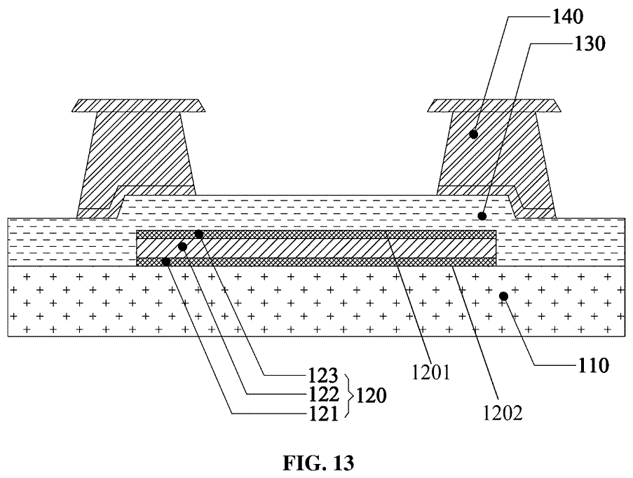

For example, referring to FIG. 13, in this embodiment, the isolation layer 1401 may be patterned by etching to form the isolation structures 140 having isolation openings.

Since the risk of the insulating layer 130 having fractures is reduced in the aforementioned steps, in the process of patterning etching the isolation layer 1401 in step S150, the risk of the etching liquid invading the first electrode 120 from a fracture of the insulating layer 130 can be reduced, thereby preventing the first electrode 120 from being damaged.

In step S230, the insulating layer 130 is etched from the isolation openings to form first openings 810, and a first opening 810 exposes at least part of the first electrode 120.

After the isolation openings are formed by etching, the insulating layer 130 can be further etched to form the structure as shown in FIG. 1.

In some possible implementations, in step S130, a first sublayer 131 of the insulating layer 130 can be formed on the side of the first electrode 120 away from the array substrate 110 by using a material having a first ratio of nitrogen content to silicon content first, and then a second sublayer 132 of the insulating layer 130 can be formed on a side of the first sublayer 131 away from the array substrate 110 by using a material having a second ratio of nitrogen content to silicon content.

The first ratio is different from the second ratio.

In some possible implementations, in step S140, the whole layer can be evaporated and then etched to form a light-emitting unit 150, a second electrode 160 and an encapsulation unit 170 that are at least partially located in the isolation opening and stacked in a direction away from the array substrate 110.

An electronic device is further provided according to the present application, which includes the display panel according to the present application or a display panel made by the method of manufacturing a display panel according to the present application. The electronic device may include a mobile phone, a tablet computer, a smart wearable device, a television, a laptop computer, a display, and other devices with display functions.

In summary, with the display panel, the method of manufacturing a display panel, and the electronic device according to the present application, the thickness of the insulating layer is set to be greater than the thickness of the first electrode, in this way, the risk of forming fractures of the insulating layer at the position covering the first electrode can be reduced, and the etching solution is prevented from damaging the first electrodes during the subsequent patterning etching of other film layers, thereby ensuring the yield of the display panel.

The technical features of the above-described embodiments may be arbitrarily combined. To make the description concise, not all possible combinations of the technical features in the above-described embodiments are described. However, as long as there is no contradiction in the combination of these technical features, they should be considered to be within the scope of this specification.

What is claimed is:

1. A display panel, comprising:
an array substrate;
an insulating layer located on a side of the array substrate, and comprising a plurality of first openings;
a plurality of first electrodes located on the side of the array substrate and arranged at intervals, the first electrodes comprising a portion exposed from a first opening of the plurality of first openings, a side surface of the first electrode covered by the insulating layer, and a thickness of the insulating layer being greater than or equal to a thickness of the first electrode; and
a light-emitting unit located on a side of the first electrode away from the array substrate.

2. The display panel according to claim 1, wherein the insulating layer comprises a first insulating portion covering the first electrode and a second insulating portion not covering the first electrode, and a ratio of a thickness of the first insulating portion to the thickness of the first electrode is greater than or equal to 1;
the thickness of the insulating layer ranges from 2000 angstroms to 4000 angstroms; and
a distance from a side of the first insulating portion away from the array substrate to the array substrate is greater than a distance from the side of the first electrode away from the array substrate to the array substrate.

3. The display panel according to claim 1, wherein the first electrode comprises a first surface on a side away from the array substrate and a second surface on a side close to the array substrate; and
an orthographic projection of the second surface on the array substrate is located within an orthographic projection of the first surface on the array substrate; or, an orthographic projection of the first surface on the array substrate is located within an orthographic projection of the second surface on the array substrate.

4. The display panel according to claim 1, wherein a material of the insulating layer is an inorganic material;
the insulating layer comprises a first sublayer and a second sublayer stacked in a direction away from the array substrate, and a silicon content in the first sublayer is different from a silicon content in the second sublayer;
a ratio of nitrogen content to silicon content in the first sublayer is a first ratio, a ratio of nitrogen content to silicon content in the second sublayer is a second ratio, and the first ratio is different from the second ratio; and
a material of the first sublayer comprises silicon nitride, and a material of the second sublayer comprises silicon nitride or silicon oxide.

5. The display panel according to claim 4, wherein the first ratio is X, the second ratio is Y, wherein 0<X<¾, 0≤Y<¾, and X>Y; and
when Y=0, a thickness of the second sublayer is less than a thickness of the first sublayer; and
when Y≠0, the thickness of the second sublayer is greater than the thickness of the first sublayer.

6. The display panel according to claim 1, wherein the first electrode comprises a first conductive layer, a second conductive layer and a third conductive layer, wherein the first conductive layer, the second conductive layer and the third conductive layer stacked in a direction away from the array substrate, and an etching rate of the second conductive layer is different from an etching rate of the first conductive layer and an etching rate of the third conductive layer;
an orthographic projection of the second conductive layer on the array substrate is located within an orthographic projection of the first conductive layer and the third conductive layer on the array substrate; and
a material of the first conductive layer and the third conductive layer comprises at least one of indium tin oxide, indium zinc oxide and indium gallium oxide, and a material of the second conductive layer comprises silver.

7. The display panel according to claim 1, further comprising:
an isolation structure located on a side of the insulating layer away from the array substrate, wherein the isolation structure comprises an isolation opening, and an orthographic projection of the first opening on the array substrate is located within an orthographic projection of the isolation opening on the array substrate;
the isolation structure comprises a support portion and a blocking portion which are stacked toward the side away from the array substrate, and an orthographic projection of the support portion on the array substrate is located within an orthographic projection of the blocking portion on the array substrate.

8. The display panel according to claim 7, wherein an orthographic projection of the first electrode on the array substrate at least partially overlaps an orthographic projection of the isolation structure on the array substrate; and
an orthographic projection of the side surface of the first electrode on the array substrate is located within the orthographic projection of the isolation structure on the array substrate.

9. The display panel according to claim 8, wherein the support portion comprises a first metal layer and a second metal layer which are stacked toward the side away from the array substrate, and the blocking portion comprises a third metal layer; and
a material of the first metal layer comprises molybdenum, a material of the second metal layer comprises aluminum, and a material of the third metal layer comprises titanium.

10. The display panel according to claim 8, further comprising a second electrode at least partially located in the isolation opening, wherein at least part of the second electrode is located on a side of the light-emitting unit away from the array substrate and is in electrical contact with the light-emitting unit, and at least another part of the second electrode is located on a side of the insulating layer away from the array substrate and is in electrical contact with the isolation structure.

11. The display panel according to claim 10, further comprising a first encapsulation layer located on a side of the second electrode away from the array substrate and at least partially located in the first opening, wherein
at least part of the first encapsulation layer is located on a side of the isolation structure away from the array substrate;
the display panel further comprises a second encapsulation layer and a third encapsulation layer, wherein the second encapsulation layer and the third encapsulation layer are located on a side of the first encapsulation layer away from the array substrate and stacked in a direction away from the array substrate; and
a material of the first encapsulation layer and the third encapsulation layer comprises inorganic materials; and a material of the second encapsulation layer comprises an organic material.

12. The display panel according to claim 7, wherein the isolation opening comprises a first isolation opening and a second isolation opening, the light-emitting unit comprises a first light-emitting unit and a second light-emitting unit which are with different light-emitting colors, at least part of the first light-emitting unit is located in the first isolation opening, and at least part of the second light-emitting unit is located in the second isolation opening;
the insulating layer comprises a first defining portion extending out of the isolation structure corresponding to the first isolation opening and a second defining portion extending out of the isolation structure corresponding to the second isolation opening, an orthographic projection of the first defining portion on the array substrate is located within an orthographic projection of the first isolation opening on the array substrate, and an orthographic projection of the second defining portion on the array substrate is located within an orthographic projection of the second isolation opening on the array substrate;
a thickness of the first defining portion and a thickness of the second defining portion are both greater than the thickness of the first electrode;
the thickness of the first defining portion is greater than the thickness of the second defining portion, or the thickness of the first defining portion is approximately equal to the thickness of the second defining portion;
the isolation opening further comprises a third isolation opening, the light-emitting unit further comprises a third light-emitting unit having a light-emitting color different from light-emitting colors of the first light-emitting unit and the second light-emitting unit, and at least part of the third light-emitting unit is located within the third isolation opening;
the insulating layer further comprises a third defining portion extending out of the isolation structure corresponding to the third isolation opening, and an orthographic projection of the third defining portion on the array substrate is located within an orthographic projection of the third isolation opening on the array substrate;
the thickness of the first defining portion, the thickness of the second defining portion and a thickness of the third defining portion are all greater than the thickness of the first electrode;
the thickness of the second defining portion is greater than the thickness of the third defining portion, or the thickness of the second defining portion is approximately equal to the thickness of the third defining portion.

13. The display panel according to claim 1, comprising a display area and a non-display area at least partially surrounding the display area, wherein the first electrode is located in the display area, and the display panel further comprises signal wiring arranged in a same layer as the first electrode and located in the non-display area; and the insulating layer continuously covers a side surface of the signal wiring and a side of the signal wiring away from the array substrate; and
the thickness of the insulating layer is greater than or equal to a thickness of the signal wiring.

14. A display panel, comprising:
an array substrate;
an insulating layer located on one side of the array substrate, wherein the insulating layer comprises first openings;
a plurality of first electrodes located on one side of the array substrate and arranged at intervals, wherein a first electrode of the plurality of first electrodes comprises a portion exposed from a first opening of the first openings, the insulating layer comprises a first insulating portion covering the first electrode and a second insulating portion staggered with the first electrode, and a thickness of the insulating layer at a junction of the first insulating portion and the second insulating portion is greater than a thickness of the first electrode corresponding to the first insulating portion;
a light-emitting unit located on a side of the first electrode away from the array substrate; and
a second electrode located on a side of the light-emitting unit away from the array substrate.

15. The display panel according to claim 14, wherein the insulating layer covers a side wall of the first electrode; or, a material of the insulating layer is an inorganic material;
the insulating layer comprises a first sublayer and a second sublayer which are stacked in a direction away from the array substrate, a ratio of nitrogen content to silicon content in the first sublayer is a first ratio, a ratio of nitrogen content to silicon content in the second sublayer is a second ratio, and the first ratio is different from the second ratio; and
a material of the first sublayer comprises silicon nitride, and a material of the second sublayer comprises silicon nitride or silicon oxide.

16. The display panel according to claim 15, wherein the first ratio is X, the second ratio is Y, wherein 0<X<¾, 0≤Y<¾, and X>Y; and
when Y=0, a thickness of the second sublayer is less than a thickness of the first sublayer; and
when Y≠0, the thickness of the second sublayer is greater than the thickness of the first sublayer.

17. The display panel according to claim 15, wherein an orthographic projection of the first electrode on the array substrate at least partially overlaps an orthographic projection of the isolation structure on the array substrate; and
an orthographic projection of the side surface of the first electrode on the array substrate is located within the orthographic projection of the isolation structure on the array substrate; or, the display panel further comprises:
an isolation structure located on a side of the insulating layer away from the array substrate, wherein the isolation structure comprises an isolation opening, and an orthographic projection of the first opening on the array substrate is located within an orthographic projection of the isolation opening on the array substrate, and
the isolation structure comprises a support portion and a blocking portion which are stacked toward the side away from the array substrate, and an orthographic projection of the support portion on the array substrate is located within an orthographic projection of the blocking portion on the array substrate.

18. A method of manufacturing a display panel, wherein the method comprises:
providing an array substrate;
arranging a plurality of first electrodes on a side of the array substrate;
providing an insulating layer on a side of the first electrodes away from the array substrate, wherein the insulating layer comprises a plurality of first openings, a first electrode of the first electrodes comprises a portion exposed from a first opening of the first openings, and a side surface of the first electrode is covered by the insulating layer; and a thickness of the insulating layer is greater than or equal to a thickness of the first electrode; and
forming a light-emitting unit located on the side of the first electrode away from the array substrate.

19. The method according to claim 18, wherein the providing an insulating layer on the side of the first electrode away from the array substrate comprises:
providing an insulating layer with a thickness greater than or equal to 1000 angstroms on the side of the first electrode away from the array substrate;
or,
the providing an insulating layer on the side of the first electrode away from the array substrate comprises:
forming a first sublayer of the insulating layer on the side of the first electrode away from the array substrate by using a material having a first ratio of nitrogen content to silicon content; and
forming a second sublayer of the insulating layer on the side of the first sublayer away from the array substrate by using a material having a second ratio of nitrogen content to silicon content, wherein the first ratio is different from the second ratio.

20. The method according to claim 18, further comprising:
providing an isolation layer on a side of the insulating layer away from the array substrate;
etching the isolation layer to form an isolation structure having an isolation opening; and
etching the insulating layer from the isolation opening to form a first opening, wherein the first opening exposes at least part of the first electrode.
